(19) United States
(12) Patent Application Publication
(10) Pub. No.: US 2026/0305182 A1
(43) Pub. Date: Oct. 1, 2026

(54) MAGNETIC RANDOM ACCESS MEMORY WITH HYBRID FREE LAYER

(71) Applicant: Samsung Electronics Co., Ltd., Gyeonggi-do (KR)

(72) Inventors: Roman CHEPULSKYY, Santa Clara, CA (US); Dmytro APALKOV, San Jose, CA (US); Jaewoo JEONG, Los Altos, CA (US); FNU IKHTIAR, San Jose, CA (US)

(21) Appl. No.: 19/350,400

(22) Filed: Oct. 6, 2025

Related U.S. Application Data
(60) Provisional application No. 63/781,618, filed on Apr. 1, 2025.

(51) Int. Cl. H10N 50/85; G11C 11/16; H10N 50/01; H10N 50/10

(52) U.S. Cl. CPC H10N 50/85; G11C 11/161; H10N 50/01; H10N 50/10

(57) ABSTRACT

A magnetic random access memory (MRAM) is provided. The MRAM includes: a first layer; a second layer; and a first free layer (FL) disposed between the first layer and the second layer, wherein the first FL includes an Mn-based alloy, and wherein a first portion of the first FL adjacent to the first layer or adjacent to the second layer has an fcc-crystal phase, and a second portion of the first FL adjacent to the first layer or adjacent to the second layer has a bcc-crystal phase.

### CROSS-REFERENCE TO RELATED APPLICATION

This application claims the priority benefit under 35 U.S.C. § 119(e) of U.S. Provisional Application No. 63/781,618, filed on Apr. 1, 2025, the disclosure of which is incorporated by reference in its entirety as if fully set forth herein.

### TECHNICAL FIELD

The disclosure generally relates to magnetic random access memory (MRAM) devices. More particularly, the subject matter disclosed herein relates to free layer architectures for improving MRAM device performance.

### BACKGROUND

Non-volatile memory technologies are widely used in modern electronic devices to retain data without power. Examples include flash memory, phase-change memory (PCM), resistive random access memory (ReRAM), and MRAM. MRAM stores data using magnetic states rather than electric charge and can provide advantages such as fast access speed, low power consumption, and high endurance. MRAM devices typically rely on magnetic tunnel junctions (MTJs), which include a free layer (FL) and a reference layer (RL) separated by a tunneling barrier. Data is stored based on the relative magnetic orientation of the FL and the RL.

### SUMMARY

Accordingly, an aspect of the disclosure provides an MRAM with a hybrid FL that exhibits perpendicular magnetic anisotropy (PMA) and tunnel magnetoresistance (TMR) within a single layer. The FL includes a uniform magnetic material, such as Mn3Ge or related alloys, and is configured to have a gradual in-plane lattice parameter from bottom to top. This gradient is induced by a lattice mismatch between a low-lattice-parameter substrate (e.g., SrO) and a high-lattice-parameter capping layer (e.g., MgO or CoAl). A lower region of the FL adjacent to the substrate exhibits PMA, while an upper region of the FL adjacent to the capping layer exhibits TMR. This structure eliminates the need for separate TMR and PMA layers, improving switching performance, simplifying integration, and enhancing scalability.

In an embodiment, an MRAM includes a first layer; a second layer; and a first FL disposed between the first layer and the second layer, wherein the first FL includes an Mn-based alloy, and wherein a first portion of the first FL adjacent to the first layer or adjacent to the second layer has an fcc-crystal phase, and a second portion of the first FL adjacent to the first layer or adjacent to the second layer has a bcc-crystal phase.

In an embodiment, a system includes an MRAM including: a first layer; a second layer; and an FL disposed between the first layer and the second layer, wherein the FL includes an Mn-based alloy, and wherein a first portion of the FL adjacent to the first layer or adjacent the second layer has an fcc-crystal phase, and a second portion of the FL adjacent to the first layer or adjacent to the second layer has a bcc-crystal phase.

In an embodiment, a method of fabricating an MRAM device includes: forming a first layer; forming a second layer; and forming an FL between the first layer and the second layer, wherein the FL includes an Mn-based alloy, and wherein a first portion of the FL adjacent to the first layer or adjacent to the second layer has an fcc-phase, and a second portion of the FL adjacent to the first layer or adjacent to the second layer has a bcc-phase.

### BRIEF DESCRIPTION OF THE DRAWINGS

In the following section, the aspects of the subject matter disclosed herein will be described with reference to exemplary embodiments illustrated in the figures, in which:

FIG. 1 is a diagram illustrating a portion of an MRAM including a substrate, a hybrid FL, and a capping layer, according to an embodiment;

FIG. 2 is a diagram illustrating a portion of an MRAM including a substrate, a hybrid FL, an insertion layer, and a capping layer to facilitate lattice transition, according to an embodiment;

FIG. 3 is a diagram illustrating a portion of an MRAM including a symmetrical hybrid FL configuration with first and second hybrid FLs, an intermediate insertion layer, and tunneling barriers, according to an embodiment;

FIG. 4 is a diagram illustrating a portion of an MRAM including a substrate, a hybrid FL, and a capping layer with a reversed lattice parameter gradient compared to FIG. 1, according to an embodiment;

FIG. 5 is a diagram illustrating a portion of an MRAM including an amorphous substrate, a hybrid FL, and a capping layer to promote a stable magnetic phase, according to an embodiment;

FIG. 6 is a diagram illustrating a portion of an MRAM including a crystalline substrate, a hybrid FL, and an amorphous capping layer to form a reversed lattice gradient, according to an embodiment;

FIG. 7 is a diagram illustrating a portion of an MRAM including a crystalline substrate, a hybrid FL, and an amorphous capping layer to enable a bottom-up transition from PMA to TMR, according to an embodiment;

FIG. 8 is a diagram illustrating a portion of an MRAM including an amorphous substrate, a hybrid FL, and a crystalline capping layer to enable a top-down transition from TMR to PMA, according to an embodiment;

FIG. 9 is a diagram illustrating a bottom FL spin-transfer torque MRAM (STT-MRAM) including a seed layer, a substrate, a hybrid FL, a tunneling barrier, reference layers, an RKKY spacer, and a capping layer, according to an embodiment;

FIG. 10 is a diagram illustrating a top FL STT-MRAM with an alternative layer ordering including a seed layer, reference layers with an RKKY spacer, a tunneling barrier, a hybrid FL, and a capping layer, according to an embodiment;

FIG. 11 is a diagram illustrating a dual MJT STT-MRAM in which a hybrid FL is shared between two tunneling junctions, according to an embodiment;

FIG. 12 is diagram illustrating a spin-orbit torque MRAM (SOT-MRAM) including an SOT line, an oxide layer, a hybrid FL, a tunneling barrier, reference layers, an RKKY spacer, and a capping layer, according to an embodiment;

FIG. 13 includes flowcharts each illustrating a method of making an MRAM device, according to an embodiment; and

FIG. 14 is a block diagram of an electronic device, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments.

Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. The dimensions of some of the elements may be exaggerated relative to other elements for clarity. For example, the dimensions of layers and regions may be exaggerated for clarity of illustration.

Further, if considered appropriate, reference numerals may be repeated among the figures to indicate corresponding and/or analogous elements. That is, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” can include any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

“First layer” as used herein can include a layer adjacent to a first portion of the FL, which may function as either a substrate or a capping layer. Some examples of “first layer” include oxide or compound materials such as SrO, MgO, CoAl, MgAlO, and BaO. “FL” as used herein can include a free layer of magnetic material in an MRAM stack. Some examples of “FL” include magnetic materials such as Mn3Ge, Mn2CoGe, Mn3Ga, Mn2CoGa, Mn3Si, Mn2CoSi, Mn3Al, and MnAl. “Second layer” as used herein can include a layer adjacent to a second portion of the FL, opposite the first layer, and may also function as either a substrate or a capping layer. Some examples of “second layer” are SrO, MgO, CoAl, MgAlO, and BaO. “PMA” as used herein can include perpendicular magnetic anisotropy, which provides thermal stability by aligning magnetic moments perpendicular to the plane of a thin film. Some examples of “PMA” can be observed in certain crystal structures, such as face-centered cubic (fcc)-like phases that may be induced by compressive strain. Some examples of fcc-like crystal structures can include those exhibited by metals such as Cu, Ni, or Pt, or strain-induced phases of Mn-based alloys. Compressive strain as used herein can include a reduction in lattice spacing within a material that occurs when the material is subjected to forces or lattice mismatches causing it to contract. “TMR” as used herein can include tunnel magnetoresistance, which enhances readout contrast by spin-dependent tunneling. Some examples of “TMR” can be observed in certain crystal structures, such as body-centered cubic (bcc)-like phases associated with high spin polarization. “Lattice parameter” as used herein can include the in-plane spacing of atoms in a crystalline material, which may influence strain and crystal phase in adjacent layers. Some examples of “lattice parameter” can include ranges of about 3.4 Å to about 3.8 Å (e.g., SrO) and about 3.9 Å to about 4.5 Å (e.g., MgO, CoAl). These ranges are provided as examples for certain structures described herein, and other lattice parameter values may also be used. The particular range can vary depending on material selection, processing conditions, or device architecture, and can be optimized or determined based on experimental measurements or computational modeling. Accordingly, the disclosed values should not be construed as limiting.

For the sake of brevity, techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein but known to a person of ordinary skill in the art. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), etc. Semiconductor doping is the modification of electrical properties by doping, e.g., transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the structures that make up an IC device, lithography and etch pattern transfer steps are repeated multiple times. Each pattern being printed on the wafer is aligned to the previously formed patterns and slowly the conductors, insulators and selectively doped regions are built up to form the final device.

To achieve high performance in an MRAM, it is often desirable for the FL to exhibit PMA for thermal stability and TMR for high readout signal contrast. Achieving both PMA and TMR within a single magnetic layer, however, can present challenges. In some respects, device designs have explored using separate magnetic layers or multilayer stacks, such as positioning a TMR-generating layer (e.g., CoFeB) in combination with a PMA-supporting layer (e.g., Mn-based alloys).

In some implementations, separating the TMR and PMA functions into distinct layers may lead to tradeoffs in device characteristics. For instance, the use of multiple layers can increase stack thickness and complexity, which may in turn affect switching efficiency, write current requirements, and scalability. Additionally, interactions between adjacent layers, such as structural mismatches or interlayer diffusion, can influence long-term magnetic performance.

The description of these technologies and approaches is provided for general background and is not intended to constitute an admission that such technologies or approaches are prior art with respect to the present disclosure.

Embodiments of the present disclosure provide an MRAM that includes a hybrid FL that exhibits PMA and TMR within a magnetic film. For example, the hybrid FL may be implemented in one or more layers. Rather than relying on separate layers or decoupled structures to achieve these properties, the disclosure uses a uniform magnetic material such as Mn3Ge or related alloys and leverages lattice-induced strain to vary its magnetic behavior.

A lattice mismatch is introduced between a low-lattice-parameter substrate and a high-lattice-parameter capping layer, which induces a gradient in the in-plane lattice parameter across the FL. This gradient results in the lower portion of the FL exhibiting PMA and the upper portion of the FL exhibiting TMR. By unifying these properties in one or more layers, the disclosure improves switching performance, reduces stack complexity, and enables better scalability for advanced MRAM applications.

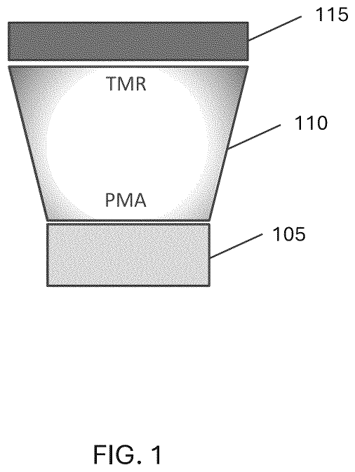

FIG. 1 illustrates a portion of an MRAM including a substrate, a hybrid FL, and a capping layer, according an embodiment. For example, the MRAM includes a substrate 105, a hybrid FL 110 disposed on the substrate 105, and a capping layer 115 disposed on the hybrid FL 110.

The substrate 105 includes a material having a relatively low in-plane lattice parameter, such as strontium oxide (SrO), in the range of approximately 3.4 Å to 3.8 Å. The substrate 105 induces in-plane compressive strain in the portion of the hybrid FL 110 adjacent to it, promoting a fcc-like crystal structure that results in PMA. The substrate 105 may have a thickness of about 2 nanometers to about 10 nanometers.

The hybrid FL 110 can include a contiguous magnetic material such as Mn3Ge, Mn2CoGe, Mn3Ga, Mn2CoGa, Mn3Si, Mn2CoSi, Mn3Al, or MnAl, which are examples of manganese-based intermetallic compounds (e.g., Heusler-type alloys) used as magnetic materials in spintronic devices. In some embodiments, variations of these compounds may be used provided that the material supports the desired lattice parameter gradient and dual magnetic properties of the hybrid FL 110, including PMA and TMR. The hybrid FL 110 can exhibit a vertical gradient in its in-plane lattice parameter, increasing from the bottom toward the top of the FL 110. This gradient is induced by the lattice mismatch between the substrate 105 and the capping layer 115. As a result of this gradient, a lower region of the hybrid FL 110 adjacent to the substrate 105 may exhibit PMA, while an upper region of the hybrid FL 110 adjacent to the capping layer 115 may exhibit TMR, which can be associated with a bcc-like structure having enhanced spin polarization compared to other crystal structures such as fcc-like phases. The hybrid FL 110 may have a thickness in a range of about 0.5 nanometers to about 7 nanometers, although other thicknesses may also be used. The particular thickness may vary depending on material selection, device architecture, or process conditions, and can be optimized based on experimental or computational results.”

The capping layer 115 cay include a material having a relatively high in-plane lattice parameter, such as MgO, CoAl, MgAlO, or BaO, in the range of about 3.9 Å to about 4.5 Å, although other thicknesses may also be used. The particular thickness may vary depending on material selection, device architecture, or process conditions, and can be optimized based on experimental or computational results. The capping layer 115 can induce in-plane tensile strain in the upper region of the hybrid FL 110, facilitating the formation of the bcc-like crystal structure conducive to TMR. The capping layer 115 may have a thickness of about 1 nanometers to about 5 nanometers.

As shown in FIG. 1, the MRAM stack unifies PMA and TMR properties within a single magnetic layer, enabling improved switching characteristics, simplified integration, and reduced complexity compared to MRAM stacks that rely on decoupled or multilayer magnetic structures.

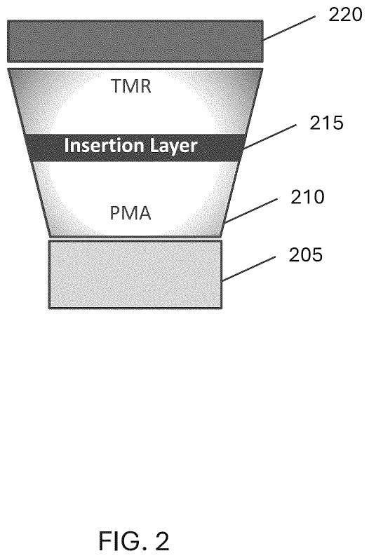

FIG. 2 illustrates a portion of an MRAM, according to an embodiment which incorporates an insertion layer to facilitate lattice transition within a hybrid FL. The MRAM includes a substrate 205, a hybrid FL 210, an insertion layer 215 and a capping layer 220.

Similar to FIG. 1, the substrate 205 may include a material having a relatively lower lattice parameter (e.g., about 3.4 Å to about 3.8 Å, such as SrO) compared to the lattice parameter of the capping layer 220, which may include a material having a relatively higher lattice parameter (e.g., about 3.9 Å to about 4.5 Å, such as MgO, CoAl, MgAlO, or BaO). The hybrid FL 210 can include a uniform magnetic material such as Mn3Ge or a related alloy, where “uniform” can refer to characteristics such as a consistent composition, density, and/or crystallographic structure across the layer. is the hybrid FL 210 may be configured to exhibit PMA near the substrate 205 and TMR near the capping layer 220, which can be associated with strain-induced crystal phase transitions.

The insertion layer 215 can be positioned within or adjacent to the hybrid FL 210 and can be configured to facilitate the lattice mismatch between the lower and upper regions of the hybrid FL 210. The insertion layer 215 may include a magnetic or non-magnetic material and may smooth the strain transition between the compressive region near the substrate 205 and the tensile region near the capping layer 215. In other words, the insertion layer 215 may reduce the abruptness of the mismatch. This helps promote structural stability, maintain interface quality, and enhance the consistency of the PMA and TMR characteristics across the hybrid FL 210. Example materials for the insertion layer 215 may include, for example, CoAl or other compounds with intermediate lattice parameters.

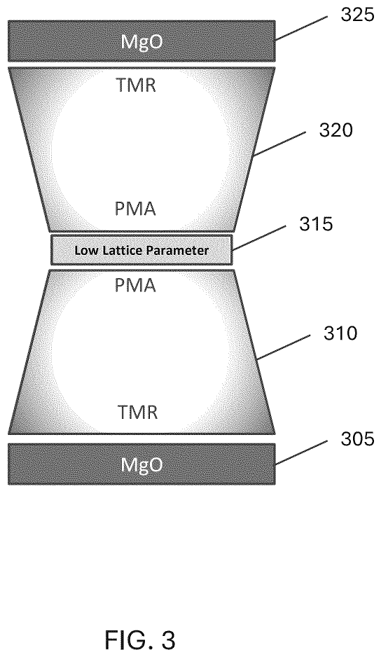

FIG. 3 illustrates a portion of an MRAM, according to an embodiment, which implements a symmetrical hybrid FL configuration. This embodiment can include a bottom tunneling barrier 305, a first hybrid FL 310, an intermediate insertion layer 315, a second hybrid FL 320 and a top tunneling barrier 325.

The first hybrid FL 310 and the second hybrid FL 320 may each be formed of a uniform magnetic material such as Mn3Ge or related alloys, and each may be configured to exhibit a vertical gradient in its in-plane lattice parameter. This enables each hybrid FL to have PMA in regions adjacent to lower-lattice-parameter interfaces and TMR in regions adjacent to higher-lattice-parameter interfaces.

The intermediate insertion layer 315 can be disposed between the first and second hybrid FLs 310 and 320 and can promote lattice compatibility and magnetic coupling between them. The intermediate insertion layer 315 may include a thin magnetic or non-magnetic material with a lattice parameter that facilitates the transition between the adjacent regions of the two hybrid FLs 310 and 320. The use of two opposing gradient FLs (e.g., 310 and 320) in combination with an insertion layer (e.g., 315) may enable the structure to be implemented in dual-MTJ configurations. In such configurations, the opposing gradients can promote a more symmetrical magnetic response, while the insertion layer may help stabilize the interfaces between the FLs. This symmetry and stability can, in some cases, contribute to improved consistency in read and write performance.

The bottom tunneling barrier 305 and top tunneling barrier 325 may be positioned adjacent to the respective hybrid FLs 310 and 320 and may include high-lattice-parameter materials such as MgO or similar oxides to enable spin-dependent tunneling. This symmetrical structure may support bidirectional switching and, in some cases, can provide dual read paths. As used herein, “dual read paths” can include the ability of the device to perform read operations through either of the tunneling barriers.

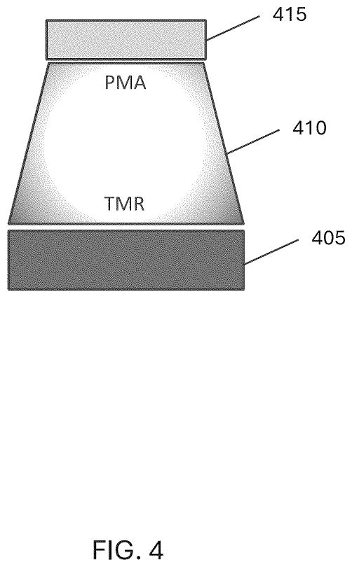

FIG. 4 illustrates a portion of an MRAM, according to an embodiment, which is a variation of the structure shown in FIG. 1, but with a reversed lattice parameter gradient. The MRAM in FIG. 4 includes a substrate 405, a hybrid FL 410 and a capping layer 415.

In this embodiment, the substrate 405 includes a high-lattice-parameter material, such as MgO, CoAl, MgAlO, or BaO, which induces tensile strain in the lower region of the hybrid FL 410. For example, the substrate 405 may have a relatively higher lattice parameter, such as about 3.9 Å to about 4.5 Å, compared to other materials in the stack (e.g., SrO with a lattice parameter of about 3.4 Å to about 3.8 Å). The substrate 405 may have a thickness of about 2 nanometers to about 10 nanometers, although other thicknesses may be used. The thickness of the substrate 405 may be selected to provide a continuous, stable film that imparts the desired lattice influence/strain to the adjacent region of the hybrid FL 410. Conversely, the capping layer 415 includes a low-lattice-parameter material, such as SrO, which induces compressive strain in the upper region of the hybrid FL 410. For example, the capping layer 415 may have a relatively lower lattice parameter such as about 3.4 Å to about 3.8 Å, compared to the substrate 405. The capping layer 415 may have a thickness of about 1 nanometers to about 5 nanometers, although other thicknesses may be used. The thickness of the capping layer 415 may be chosen to provide sufficient lattice influence on the adjacent region of the hybrid FL 410.

The hybrid FL 410 may be formed of a magnetic material, such as Mn3Ge or a related compound, and may exhibit a gradual decrease in its in-plane lattice parameter from bottom to top. As a result, the lower portion of the hybrid FL 410 adjacent to the substrate 405 may promote a bcc-like crystal structure, which can in some cases be associated with higher spin polarization and enhanced TMR. The upper portion of the hybrid FL 410 adjacent to the capping layer 415 may promote an fcc-like crystal structure, which can in some cases be associated with magnetic moment alignment perpendicular to the film plane and enhanced PMA. While bcc-like and fcc-like phases are provided as illustrative examples, other crystal structures or strain-induced phases may also influence spin polarization and anisotropy, and the present disclosure is not limited to the specific examples described. The hybrid FL 410 may have a thickness of about 0.5 nanometers to about 7 nanometers, although other thicknesses, such as those described above for the hybrid FLs 110 and 210, may be used.

This inverted gradient structure may be used in cases where device integration or fabrication constraints favor placing the TMR-active region below the PMA-active region. For example, certain back-end-of-line (BEOL) integration flows or CMOS-compatible processes may impose thickness, patterning, or alignment requirements that make it advantageous to position the TMR-generating portion of the FL closer to underlying circuitry.

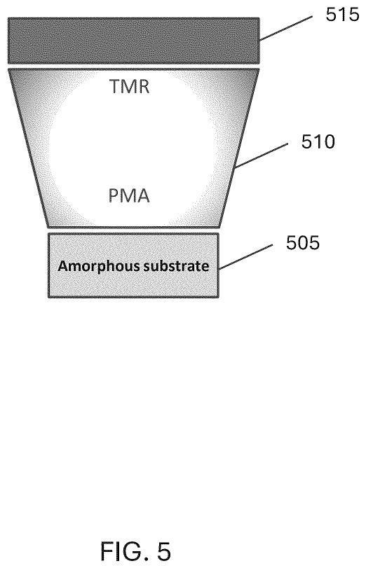

FIG. 5 illustrates a portion of an MRAM, according to an embodiment, which employs an amorphous substrate. Use of an amorphous substrate may promote a stable magnetic phase in the hybrid FL by reducing lattice mismatch and interfacial strain compared to crystalline substrates. These effects can, in some cases, contribute to improved magnetic stability. The MRAM may include an amorphous substrate 505, a hybrid FL 510 and a capping layer 515.

The amorphous substrate 505 may include an amorphous form of MgAlO or another suitable amorphous oxide. Additional examples of amorphous oxides can include SiO₂, Al₂O₃, HfO₂, ZrO₂, Ta₂O₅, or amorphous forms of perovskite-type oxides. Unlike crystalline substrates, the amorphous substrate 505 may not impose a rigid lattice parameter on the adjacent hybrid FL 510. Instead, it can enable the bottom region of the hybrid FL 510 to have a stable structure, such as an fcc-like phase, that supports PMA. The amorphous substrate 505 may have a thickness of about 2 nanometers to about 10 nanometers, although other thicknesses may be used.

The hybrid FL 510 may include a magnetic material such as Mn3Ge, Mn2CoGe, Mn3Ga, Mn 3Al, or MnAl. The hybrid FL 510 may have a thickness of about 0.5 nanometers to about 7 nanometers. A lattice parameter gradient may still be established within the hybrid FL 510 by using a crystalline capping layer 515 with a relatively high lattice parameter (e.g., MgO, CoAl, MgAlO, or BaO). For example, the capping layer 515 may have a high lattice parameter in the range of approximately 3.9 Å to 4.5 Å. The capping layer 515 may induce tensile strain in the upper portion of the hybrid FL 510 to promote a bcc-like structure and enable TMR in that region. The capping layer 515 may have a thickness of about 1 nanometers to about 5 nanometers. The materials of the hybrid FL 510 may be similar to those described above for the hybrid FL 110. Certain features of the capping layer 515, such as thickness and lattice parameter, may be similar to those of the capping layer 415.

This embodiment allows the use of a non-crystalline substrate while still achieving the benefits of PMA and TMR in a single magnetic layer.

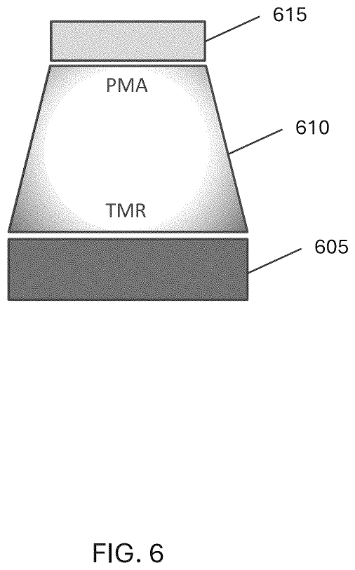

FIG. 6 illustrates a portion of an MRAM, according to an embodiment, which represents a variation of FIG. 5 with a reversed lattice gradient direction. The MRAM may include a substrate 605, a hybrid FL 610 and a capping layer 615.

The substrate 605 includes a crystalline material having a high lattice parameter in the range of approximately 3.9 Å to 4.5 Å, such as MgO, CoAl, MgAlO, or BaO, although other materials may be used. The crystalline substrate imposes tensile in-plane strain on the bottom region of the hybrid FL 610, promoting a bcc-like phase that supports TMR. The substrate 605 may have a thickness of about 2 nanometers to about 10 nanometers. The materials and thickness of the substrate 605 may be similar to those of the substrate 405.

The hybrid FL 610 may have a thickness in the range of approximately 0.5 nm to 7 nm and may include a magnetic material selected from Mn3Ge, Mn2CoGe, Mn3Ga, Mn3Al, and MnAl, although other materials may be used. The hybrid FL 610 may exhibit a vertical gradient in its in-plane lattice parameter, decreasing from bottom to top due to the strain effects from the substrate 605 and the absence of strain effect from the capping layer 615. The thickness and materials of the hybrid FL 610 may be similar to those of the hybrid FL 510.

The capping layer 615 may include an amorphous oxide material, such as amorphous MgAlO, although other materials may be used, and may not impose a lattice parameter on the top of the hybrid FL 610. This allows the upper portion of the hybrid FL 610 to have a lower lattice parameter phase, such as fcc-like, supporting PMA. The capping layer 615 may have a thickness of about 1 nanometers to about 5 nanometers. The thickness of the capping layer 615 may be similar to that of the capping layer 515. Certain materials of the capping layer 615 may be similar to that of the capping layer 515.

In this embodiment, the gradient in lattice parameter may transition from high (adjacent the substrate 605) to low (adjacent the capping layer 615), which is the opposite direction of the gradient in FIG. 5. The configuration allows the MRAM to maintain unified TMR and PMA behavior within a single film.

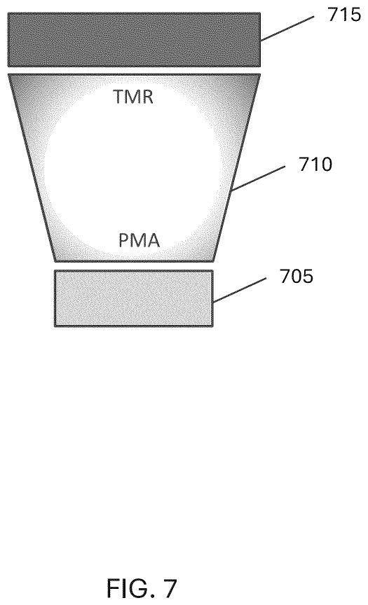

FIG. 7 illustrates a portion of an MRAM, according to an embodiment, which uses an amorphous capping layer to influence the magnetic behavior of the hybrid FL. The MRAM may include a substrate 705, a hybrid FL 710 and a capping layer 715.

The substrate 705 may include a crystalline material having a low lattice parameter in the range of approximately 3.4 Å to 3.8 Å, such as SrO, although other materials may be used. This may induce compressive strain in the lower portion of the hybrid FL 710 to promote a fcc-like crystal structure and enable PMA. The substrate 705 may have a thickness of about 2 nanometers to about 10 nanometers. The materials of the substrate 705 may be similar to that of the substrate 205. The thickness of the substrate 705 may be similar to that of the substrate 105.

The hybrid FL 710 may have a thickness in the range of about 0.5 nm to about 7 nm and may be formed of a magnetic material such as Mn2CoGa, Mn3Si, or Mn2CoSi, although other magnetic materials may be used such as those employed in an MTJ. The thickness of the hybrid FL 710 may be similar to that of the hybrid FL 605. A vertical gradient in its in-plane lattice parameter may be induced across the hybrid FL 710 due to the mismatch between the crystalline substrate 705 and the relaxed lattice parameter at the top of the hybrid FL 710.

The capping layer 715 includes an amorphous oxide, such as amorphous MgAlO, which allows the upper region of the hybrid FL 710 to have a bcc-like crystal structure related to bulk and associated with enhanced TMR, although other materials may be used. The amorphous capping layer 715 promotes relaxation toward a high lattice parameter configuration in the upper region of the hybrid FL 710 without imposing rigid crystalline constraints. The capping layer 715 may have a thickness of about 1 nanometers to about 5 nanometers. The thickness of the capping layer 715 may be similar to that of the capping layer 515. Certain materials of the capping layer 715 may be similar to that of the capping layer 515.

This configuration can enable a bottom-up transition from PMA to TMR within the hybrid FL 710. This can be used by device architectures that could benefit from having the TMR-generating region near the capping layer 715.

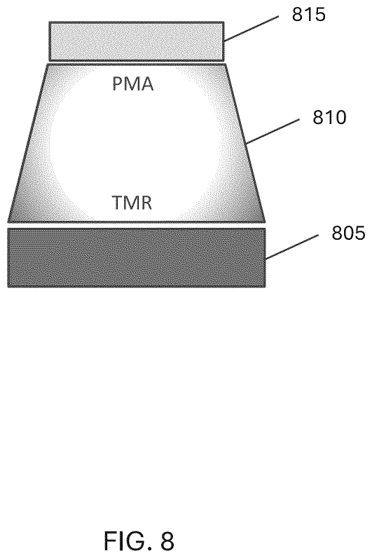

FIG. 8 illustrates a portion of an MRAM, according to an embodiment, which is a variation of FIG. 7 with a reversed lattice gradient direction. The MRAM may include a substrate 805, a hybrid FL 810 and a capping layer 815.

The substrate 805 may include an amorphous oxide material, such as amorphous MgAlO, which allows the bottom portion of the hybrid FL 810 to relax into a bulk lattice parameter configuration, although other materials may be used. This can promote a bcc-like crystal structure in the lower region of the hybrid FL 810, supporting TMR. The substrate 805 may have a thickness of about 2 nanometers to about 10 nanometers. The material of the substrate 805 may be similar to that of the substrate 505, and the thickness of the substrate 805 may be similar to that of the substrate 505.

The hybrid FL 810 may have a thickness in the range of about 0.5 nm to about 7 nm and may be formed of a magnetic material selected from Mn2₂CoGa, Mn3Si, or Mn2CoSi, although other materials may be used. The thickness and material of the hybrid FL 810 may be similar to those of the hybrid FL 710. The hybrid FL 810 can exhibit a vertical gradient in its in-plane lattice parameter, decreasing from bottom to top due to the difference between the bulk relaxed parameter on the amorphous substrate 805 and the crystalline capping layer 815.

The capping layer 815 may include a crystalline material having a low lattice parameter in the range of approximately 3.4 Å to 3.8 Å, such as SrO, although other materials may be used. The capping layer 815 can impose a compressive strain on the upper region of the hybrid FL 810, forming an fcc-like structure that supports PMA. The capping layer 815 may have a thickness of about 1 nanometers to about 5 nanometers. The materials and thickness of the capping layer 815 may be similar to those of the capping layer 415.

This embodiment can enable a down-top transition from TMR to PMA within the hybrid FL 810 and demonstrates the flexibility of using amorphous-crystalline layer combinations to produce a desired strain profile.

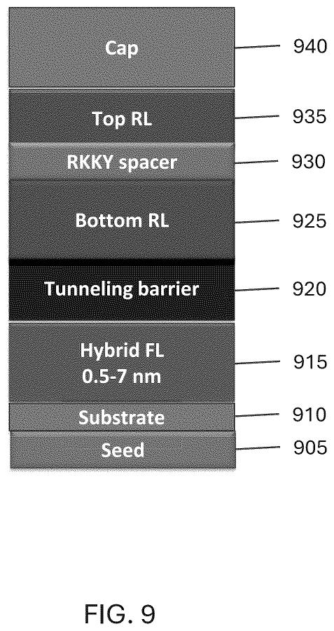

FIG. 9 is a diagram illustrating a bottom FL STT-MRAM, according to an embodiment. FIG. 9 illustrates how the hybrid FL can be incorporated into an STT-MRAM stack, showing its placement relative to other layers such as a tunneling barrier, reference layers, and a capping layer. The STT-MRAM may include a seed layer 905, a substrate 910, a hybrid FL 915, a tunneling barrier 920, a bottom reference layer (RL) 925, an Ruderman-Kittel-Kasuya-Yosida (RKKY) spacer 930, a top RL 935 and a capping layer 940.

The substrate 910 may be formed on the seed layer 905. Depending on which embodiment of FIGS. 1-8 is employed for the hybrid FL 915, the substrate 910 may include MgO, MgAlO, BaO, SrO, CoAl. The seed layer 905 may be a semiconductor wafer or other suitable base structure for MRAM integration.

The hybrid FL 915 may be disposed above the substrate 910 and may have a thickness in the range of about 0.5 nm to about 7 nm. The hybrid FL 915 may include a magnetic material such as Mn3Ge, Mn2CoGe, Mn3Ga, Mn2CoGa, Mn3Si, Mn2CoSi, Mn3Al, and MnAl, or related compounds and may exhibit PMA and TMR via a vertical in-plane lattice parameter gradient. This gradient can be established by a lattice mismatch between the underlying layers and the overlying capping layer 940, promoting PMA near the bottom of the hybrid FL 915 and TMR near the top of the hybrid FL 915, or vice versa. The thickness and materials of the hybrid FL 915 may be similar to those of the hybrid FL 810.

Depending on which embodiment of FIGS. 1-8 is employed for the hybrid FL 915, the tunneling barrier 920 may be disposed on the hybrid FL 915 and may include a high-spin-polarization oxide such as MgO, MgAlO, BaO, SrO, enabling efficient spin-dependent tunneling. Above the tunneling barrier 920 can be the bottom RL 925, which may be ferromagnetic and fixed in its magnetization direction. The RKKY spacer 930 may be used to separate the bottom RL 925 from the top RL 935, allowing for antiferromagnetic coupling between them to enhance stability.

The capping layer 940 completes the stack and may include any material suitable to cover the stack, such as Ta, W, Ti, or any other hard mask material. The gradient lattice parameter of hybrid FL 915 may be generated by the lattice parameter difference between the tunneling barrier 920 and the substrate 910.

This embodiment demonstrates how the hybrid FL 915 can be integrated into a complete STT-MRAM device architecture, while maintain its dual magnetic properties within a single film, for example.

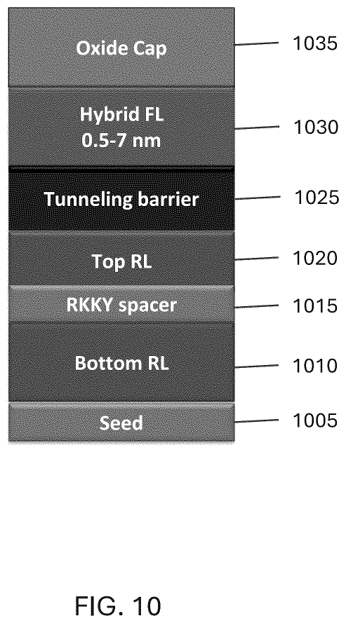

FIG. 10 is a diagram illustrating a top FL STT-MRAM, according to an embodiment, which is a variation of the STT-MRAM stack shown in FIG. 9, but with a reversed layer ordering. FIG. 10 illustrates another embodiment in which the hybrid FL is integrated into an STT-MRAM stack with a reversed layer ordering, demonstrating that the hybrid FL can be employed in different stack architectures. The structure may include a seed layer 1005, a bottom RL 1010, an RKKY spacer 1015, a top RL 1020, a tunneling barrier 1025, a hybrid FL 1030, and an oxide capping layer 1035.

The seed layer 1005 can promote crystallographic growth for the magnetic layers thereabove. The bottom RL 1010 and top RL 1020, separated by the RKKY spacer 1015, form a synthetic antiferromagnetic reference layer structure that provides a fixed magnetic orientation for STT switching. The RKKY spacer 1015 may be configured to induce antiferromagnetic coupling between the bottom and top RLs 1010 and 1020 to minimize dipolar interactions and enhance stability.

The tunneling barrier 1025, disposed above the top RL 1020, may be a non-magnetic insulator without spin polarization such as MgO, MgAlO, BaO, SrO, which facilitates efficient electron tunneling based on the relative magnetization of the hybrid FL 1030 and RLs 1010 and 1020.

Above the tunneling barrier 1025 is the hybrid FL 1030, which may be formed from a magnetic material such as Mn3Ge, Mn2CoGe, Mn3Ga, Mn3Al, or related alloys, and has a thickness in the range of approximately 0.5 nm to 7 nm. The hybrid FL 1030 exhibits a vertical gradient in the in-plane lattice parameter, which allows it to generate PMA near the bottom (adjacent the tunneling barrier 1025) and TMR near the top (adjacent the oxide capping layer 1035). The materials of the hybrid FL 1030 may be similar to those of the hybrid FL 915.

Depending on which embodiment of FIGS. 1-8 is employed for the hybrid FL 1030, the oxide capping layer 1035 may include MgO, MgAlO, BaO, SrO, CoAl, which may impose two types of stress, thus generating PMA or TMR in the upper portion of the hybrid FL 1030.

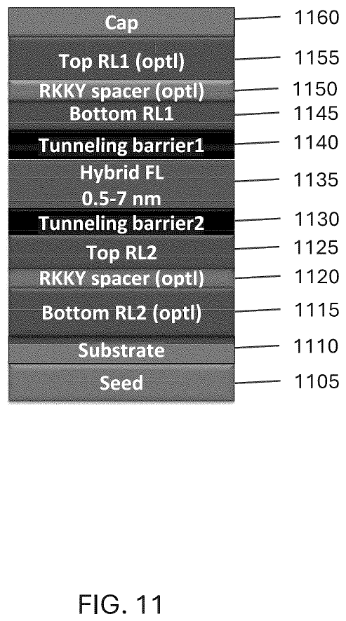

FIG. 11 illustrates a dual MJT STT-MRAM, according to an embodiment. In particular, FIG. 11 illustrates a dual-MTJ STT-MRAM configuration in which the hybrid FL is shared between two tunneling junctions, showing that the hybrid FL can be adapted for dual-MTJ architectures to support symmetrical operation. This embodiment allows for symmetrical read/write access from either side of the hybrid FL 1135. This structure may include a seed layer 1105, a substrate 1110, and an MRAM stack featuring two MTJ elements positioned on opposite sides of a hybrid FL 1135.

From the bottom up, the structure may include an optional bottom RL (RL1) 1115, which may be ferromagnetic, and an optional RKKY spacer 1120 for antiferromagnetic coupling. A top RL (RL2) 1125 may be disposed above the RKKY spacer 1120. The top RL (RL2) 1125 may interface with the second tunneling barrier 1130, formed of MgO, MgAlO, BaO, SrO or another spin-filtering oxide.

The hybrid FL 1135 can be sandwiched between the second tunneling barrier 1130 and a first tunneling barrier 1140 and may include a magnetic material such as Mn3Ge, Mn2CoGe, Mn3Ga, Mn2CoGa, Mn3Si, Mn2CoSi, Mn3Al, and MnAl, or related alloys, with a thickness of approximately 0.5 nm to 7 nm. The materials and thickness of the hybrid FL 1135 may be similar to those of the hybrid FL 1030. The hybrid FL 1135 may exhibit a vertical gradient in its in-plane lattice parameter, enabling PMA at one end and TMR at the other. This allows the hybrid FL 1135 to function as the FL for both MTJ elements in the dual-MTJ configuration.

Disposed above the hybrid FL 1135 can be the first tunneling barrier 1140, which interfaces with a bottom RL (RL1) 1145. The bottom RL (RL1) 1145 may be part of a synthetic antiferromagnetic structure including an optional RKKY spacer 1150 and an optional top RL1 1155.

A capping layer 1160 may include any material necessary to cover the stack (Ta, W, Ti, or any other hard mask material). The gradient lattice parameter of hybrid FL 1135 may be generated only by the lattice parameter difference between the first tunneling barrier 1140 and the second tunneling barrier 1130.

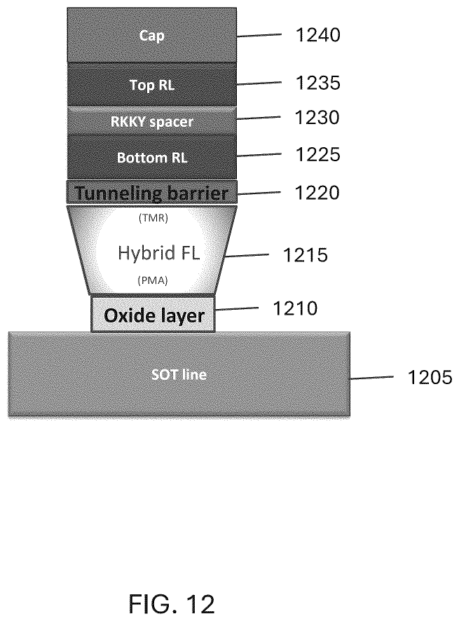

FIG. 12 illustrates an SOT-MRAM, according to an embodiment. In particular, FIG. 12 illustrates an SOT-MRAM configuration in which the hybrid FL described hereinafter is positioned above an SOT line, showing that the hybrid FL can also be implemented in SOT-based architectures in addition to STT-based designs, The structure may include an SOT line 1205, an oxide layer 1210, a hybrid FL 1215, a tunneling barrier 1220, a bottom RL 1225, an RKKY spacer 1230, a top RL 1235, and a capping layer 1240.

The SOT line 1205 may be formed of a heavy metal or related material capable of generating SOT to induce switching in the adjacent hybrid FL 1215. Example materials for the SOT line 1205 include Ta, W, Pt, Hf, as well as alloys of two or more of W, Pt, Tb, Bi, Hf, Zr, Ag, Au, Si, Cu, Cr, V, Mo, and multilayers of such materials (e.g., Au/Si, or W/Ox/W/Ox/W/Ox, where Ox denotes oxygen-treated layers). Additional materials may include oxidized variants (e.g., W with surface oxidation to increase resistivity and spin Hall angle), multilayer oxides, or topological insulators such as BiTe, BiSe, TlBiTe, TlBiSe, SbTeS, BiTeS, BiTeSe, GeSbTe, SnSbTe, GeBiTe, SnBiTe, BiSb, or BiSbSe. Heavy-metal-based antiferromagnets or ferrimagnets (e.g., AxB1−x where A=Ir, Pt, Pd, Rh and B═Mn, Fe, with 0<x<1) may also be used.

The oxide layer 1210 may be disposed between the SOT line 1205 and the hybrid FL 1215 and may have a thickness in the range of 0.4 nm to 15 nm. The oxide layer 1210 may be formed of materials such as SrO and can help control interfacial properties, enhance SOT efficiency, or stabilize the structure.

The hybrid FL 1215 may include a magnetic material selected from Mn3Ge, Mn2CoGe, Mn3Ga, Mn2CoGa, Mn3Si, Mn2CoSi, Mn3Al, or MnAl, and may have a thickness in the range of approximately 0.5 nm to 7 nm. As in previous embodiments, the hybrid FL 1215 exhibits a vertical gradient in in-plane lattice parameter, resulting in PMA near the oxide layer 1210 and TMR near the tunneling barrier 1220.

The tunneling barrier 1220 may be positioned above the hybrid FL 1215 and may be formed of MgO, CoAl, MgAlO, or BaO, or other materials that enable efficient spin-polarized tunneling for high TMR output.

The bottom RL 1225 and top RL 1235, separated by the RKKY spacer 1230, form a synthetic antiferromagnetic (SAF) reference stack. The RKKY spacer 1230 may be configured to provide antiferromagnetic coupling to reduce net dipole fields and improve thermal stability.

The capping layer 1240 completes the stack, providing protection, promoting lattice strain in the upper region of the hybrid FL 1215, and supporting the formation of a bcc-like structure. The capping layer 1240 may include any material suitable to cover the stack, such as Ta, W, Ti, or any other hard mask material. The gradient lattice parameter of hybrid FL 1215 may be generated by the lattice parameter difference between the tunneling barrier 1220 and the oxide layer 1210.

This embodiment demonstrates how the hybrid FL can be adapted for SOT-based MRAM devices while maintaining the integrated PMA and TMR characteristics in a simplified architecture.

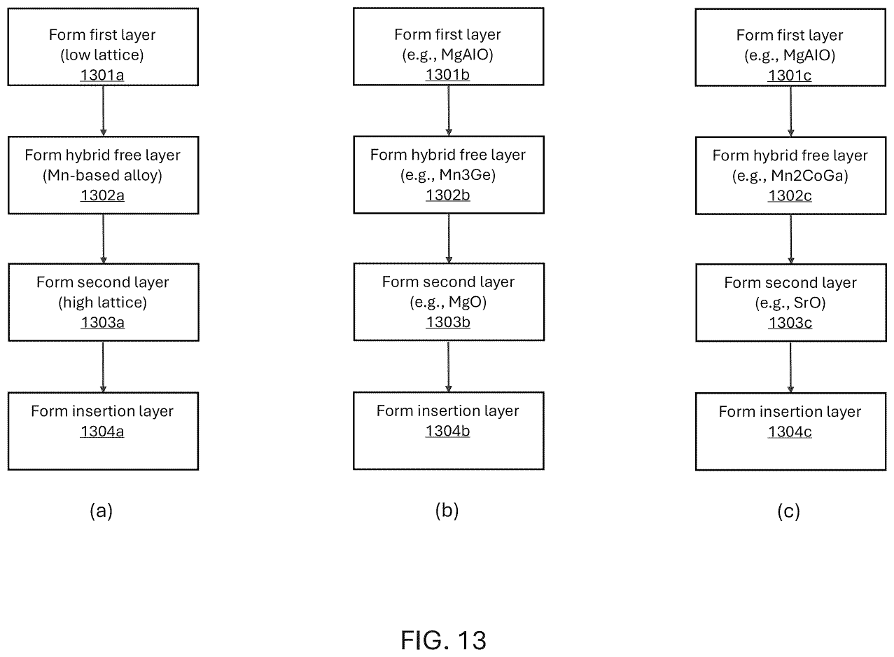

FIG. 13 includes flowcharts each illustrating a method of making an MRAM device, according to an embodiment.

FIG. 13(a) illustrates a method of fabricating an MRAM device, according to an embodiment. The method may include forming a first layer, a hybrid FL, and a second layer such that the free layer may exhibit PMA at one interface and TMR at the other.

In step 1301a, a first layer may be formed adjacent to a substrate. The first layer may include a material having a relatively lower lattice parameter (e.g., about 3.4 Å to about 3.8 Å), such as strontium oxide (SrO) or a similar oxide. This first layer may introduce compressive strain conditions that can influence the adjacent portion of the free layer to exhibit perpendicular magnetic anisotropy (PMA).

In step 1302a, a hybrid FL may be deposited on the first layer. The hybrid FL may include a magnetic material such as Mn₃Ge, Mn₂CoGe, Mn₃Ga, Mn₂CoGa, Mn₃Si, Mn₂CoSi, Mn₃Al, or MnAl. When formed between layers having different lattice parameters, the hybrid FL may exhibit a gradient in its structural and magnetic properties. For example, a first portion of the hybrid FL adjacent to the first layer may exhibit PMA, while a second portion of the hybrid FL adjacent to the second layer may exhibit TMR. This dual-function behavior arises from lattice mismatch and strain effects and allows the hybrid FL to contribute to thermal stability and enhanced readout contrast.

In step 1303a, a second layer may be formed on the hybrid FL. The second layer may include a material having a relatively higher lattice parameter (e.g., about 3.9 Å to about 4.5 Å), such as magnesium oxide (MgO), cobalt aluminum (CoAl), magnesium aluminum oxide (MgAlO), or barium oxide (BaO). The lattice parameter of the second layer can provide tensile strain that influences the adjacent portion of the hybrid FL to exhibit TMR.

In step 1304a, optional additional layers may be formed to complete the MRAM device. These layers may include an insertion layer disposed between portions of the hybrid FL to smooth strain transitions, reference layers, tunneling barriers, spacers, or capping layers. The use of such optional layers may improve interface quality, reduce abrupt mismatches in strain, or provide additional functionality depending on the device architecture (e.g., STT-MRAM or SOT-MRAM).

FIG. 13(b) illustrates a method of fabricating an MRAM device, according to an embodiment. The method may include forming a hybrid FL between a first layer and a second layer, with the hybrid FL material selected to achieve PMA at one interface and TMR at the other.

In step 1301b, a first layer may be formed, which may include a material such as magnesium aluminum oxide (MgAlO). In step 1302b, a hybrid FL may be formed on the first layer. The hybrid FL may include at least one of Mn₃Ge, Mn₂CoGe, Mn₃Ga, Mn₃Al, or MnAl. When disposed between layers having different lattice parameters, the hybrid FL may exhibit a gradient of properties such that a first portion adjacent to the first layer may exhibit PMA, while a second portion adjacent to the second layer may exhibit TMR. In step 1303b, a second layer is formed on the hybrid FL, which may include a material such as magnesium oxide (MgO), cobalt aluminum (CoAl), magnesium aluminum oxide (MgAlO), or barium oxide (BaO). In step 1304b, optional insertion layers or additional stack layers may be formed to smooth strain transitions, enhance interfacial quality, or provide further functionality depending on device requirements.

FIG. 13(c) illustrates a method of fabricating an MRAM device, according to an embodiment. The method may include forming a hybrid FL disposed between two layers, where the hybrid FL may include Mn₂CoGa, Mn₃Si, or Mn₂CoSi and may exhibit PMA and TMR at opposite interfaces.

In step 1301c, a first layer may be formed, which may include a material such as magnesium aluminum oxide (MgAlO). In step 1302c, a hybrid FL may be formed on the first layer. The hybrid FL may include at least one of Mn₂CoGa, Mn₃Si, or Mn₂CoSi. When positioned between layers of different lattice parameters, the hybrid FL may develop a gradient of structural and magnetic properties such that a first portion adjacent to the first layer may exhibit PMA, while a second portion adjacent to the second layer may exhibit TMR. In step 1303c, a second layer may be formed on the hybrid FL, which may include a material such as strontium oxide (SrO). In step 1304c, optional insertion layers or additional stack layers may be formed to smooth strain transitions, improve interfacial quality, or provide further functionality depending on the MRAM architecture.

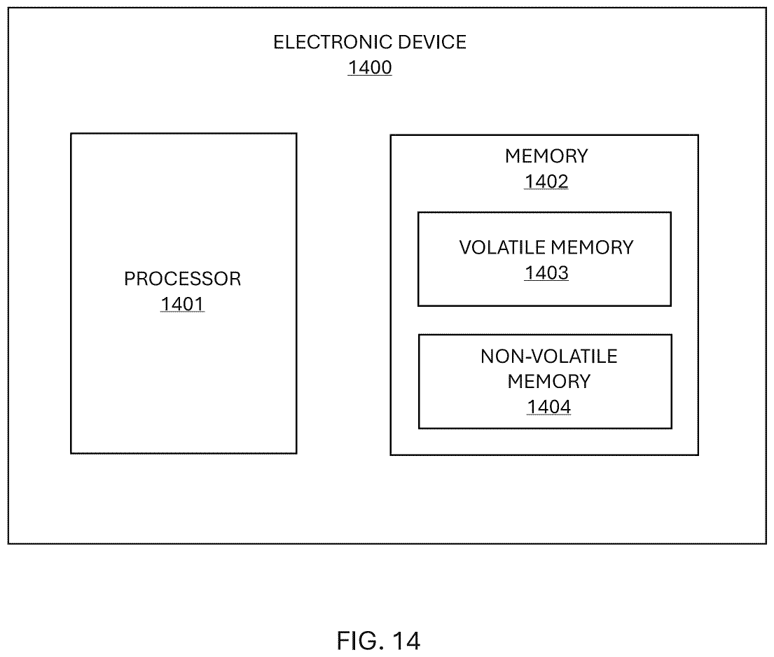

FIG. 14 is a block diagram of an electronic device, according to an embodiment.

Referring to FIG. 14, an electronic device 1400, e.g., a user equipment (UE) or a mobile terminal, includes a processor 1401 and a memory 1402. Although not illustrated in FIG. 14, dependent on the type of the electronic device 1400, the electronic device 1400 may include various additional components, such as an input device, a sound output device, a display device, an audio module, a sensor module, an interface, a haptic module, a camera module, a power management module, a battery, a communication module, a subscriber identification module (SIM), and/or an antenna module.

The processor 1401 may execute, for example, software (e.g., a program) to control at least one other component (e.g., a hardware or a software component) of the electronic device 1400, and may perform various data processing or computations. As at least part of the data processing or computations, the processor 1401 may load a command or data received from another component in volatile memory 1403, process the command or the data stored in the volatile memory 1403, and store resulting data in non-volatile memory 1404. The processor 1401 may include a main processor (e.g., a central processing unit (CPU) or an application processor, and an auxiliary processor (e.g., a graphics processing unit (GPU), an image signal processor (ISP), a sensor hub processor, or a communication processor (CP)) that is operable independently from, or in conjunction with, the main processor.

The memory 1402 may store various data used by at least one component (e.g., the processor 1401) of the electronic device 1400. The various data may include, for example, software (e.g., the program) and input data or output data for a command related thereto. The memory 1402 may include the volatile memory 1403 or the non-volatile memory 1304. The non-volatile memory 1304 may be implemented using MRAM devices that incorporate the hybrid FL structures described with respect to FIGS. 1-12. Accordingly, FIG. 14 illustrates an example of how the MRAM devices described herein can be integrated into an electronic system for data storage. This integration example demonstrates that the disclosed hybrid FL structures are not limited to stand-alone memory cells, but can be deployed within broader system architectures.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

While the present disclosure has been shown and described with reference to certain embodiments thereof, it will be understood by those skilled in the art that various changes in form and details may be made therein without departing from the spirit and scope of the disclosure as defined by the appended claims and their equivalents.

What is claimed is:

1. A magnetic random access memory (MRAM) comprising:
a first layer;
a second layer; and
a first free layer (FL) disposed between the first layer and the second layer, wherein the first FL includes an Mn-based alloy, and
wherein a first portion of the first FL adjacent to the first layer or adjacent to the second layer has an fcc-crystal phase, and a second portion of the first FL adjacent to the first layer or adjacent to the second layer has a bcc-crystal phase.

2. The MRAM of claim 1, wherein the first FL includes at least one of Mn3Ge, Mn2CoGe, Mn3Ga, Mn2CoGa, Mn3Si, Mn2CoSi, Mn3Al or MnAl.

3. The MRAM of claim 1, wherein a lattice parameter of the first FL increases from the first portion to the second portion.

4. The MRAM of claim 1, wherein the first layer includes SrO.

5. The MRAM of claim 1, wherein the second layer includes at least one of MgO, CoAl, MgAlO or BaO.

6. The MRAM of claim 1, further comprising an insertion layer between the first portion and the second portion.

7. The MRAM of claim 1, further comprising a second FL, wherein one of the first layer or the second layer is disposed between the second FL and the first FL.

8. The MRAM of claim 1, further comprising a second FL, wherein one of the first layer or the second layer is disposed between the second FL and the first FL, wherein the first layer or the second layer includes MgO.

9. A system comprising:
a magnetic random access memory (MRAM) including:
a first layer;
a second layer; and
a free layer (FL) disposed between the first layer and the second layer, wherein the FL includes an Mn-based alloy, and
wherein a first portion of the FL adjacent to the first layer or adjacent the second layer has an fcc-crystal phase, and a second portion of the FL adjacent to the first layer or adjacent to the second layer has a bcc-crystal phase.

10. The system of claim 9, wherein the Mn-based alloy is an Mn-based Heusler alloy.

11. The system of claim 9, wherein the FL includes at least one of Mn3Ge, Mn2CoGe, Mn3Ga, Mn3Al or MnAl.

12. The system of claim 9, wherein the first layer includes MgAlO.

13. The system of claim 9, wherein the second layer includes at least one of MgO, CoAl, MgAlO or BaO.

14. A method of fabricating a magnetic random access memory (MRAM) device, comprising:
forming a first layer;
forming a second layer; and
forming a free layer (FL) between the first layer and the second layer, wherein the FL includes an Mn-based alloy, and
wherein a first portion of the FL adjacent to the first layer or adjacent to the second layer has an fcc-phase, and a second portion of the FL adjacent to the first layer or adjacent to the second layer has a bcc-phase.

15. The method of claim 14, wherein the FL includes at least one of Mn2CoGa, Mn3Si or Mn2CoSi.

16. The method of claim 14, wherein the first FL includes at least one of Mn3Ge, Mn2CoGe, Mn3Ga, Mn3Al or MnAl.

17. The method of claim 14, wherein the first layer includes MgAlO.

18. The method of claim 14, wherein the second layer includes SrO.
